(19) United States
(12) Patent Application Publication
(10) Pub. No.: US 2011/0308585 A1
(43) Pub. Date: Dec. 22, 2011

(54) DUAL TRANSPARENT CONDUCTIVE MATERIAL LAYER FOR IMPROVED PERFORMANCE OF PHOTOVOLTAIC DEVICES

(75) Inventors: Pratik P. Joshi, Cliffside Park, NJ (US); Young-Hee Kim, Mohegan Lake, NY (US); Steven E. Steen, Peekskill, NY (US)

(73) Assignee: INTERNATIONAL BUSINESS MACHINES CORPORATION, Armonk, NY (US)

(21) Appl. No.: 12/816,745

(22) Filed: Jun. 16, 2010

(51) Int. Cl. H01L 31/0224; H01L 31/105; H01L 31/18

(52) U.S. Cl. 136/255; 438/72; 257/E31.126; 257/E31.061

(57) ABSTRACT

A dual transparent conductive material layer is provided between a p-doped semiconductor layer and a substrate layer of a photovoltaic device. The dual transparent conductive material layer includes a first transparent conductive material and a second transparent conductive material wherein the second transparent conductive material is nano-structured. The nano-structured second transparent conductive material acts as a protective layer for the underlying first transparent conductive material. The nano-structured transparent conductive material provides a benefit of a higher Eg of the underlying first transparent conductive material surface and a very high resilience to hydrogen plasma from the nano-structures during the formation of the p-doped semiconductor layer.

### BACKGROUND

The present disclosure relates to photovoltaic devices, and more particularly to photovoltaic devices such as, for example, solar cells, including a dual transparent conductive material layer and a method of forming the same.

A photovoltaic device is a device that converts the energy of incident photons to electromotive force (e.m.f.). Typical photovoltaic devices include solar cells, which are configured to convert the energy in the electromagnetic radiation from the Sun to electric energy. Each photon has an energy given by the formula E=hν, in which the energy E is equal to the product of the Plank constant h and the frequency ν of the electromagnetic radiation associated with the photon.

A photon having energy greater than the electron binding energy of a matter can interact with the matter and free an electron from the matter. While the probability of interaction of each photon with each atom is probabilistic, a structure can be built with a sufficient thickness to cause interaction of photons with the structure with high probability. When an electron is knocked off an atom by a photon, the energy of the photon is converted to electrostatic energy and kinetic energy of the electron, the atom, and/or the crystal lattice including the atom. The electron does not need to have sufficient energy to escape the ionized atom. In the case of a material having a band structure, the electron can merely make a transition to a different band in order to absorb the energy from the photon.

The positive charge of the ionized atom can remain localized on the ionized atom, or can be shared in the lattice including the atom. When the positive charge is shared by the entire lattice, thereby becoming a non-localized charge, this charge is described as a hole in a valence band of the lattice including the atom. Likewise, the electron can be non-localized and shared by all atoms in the lattice. This situation occurs in a semiconductor material, and is referred to as photogeneration of an electron-hole pair. The formation of electron-hole pairs and the efficiency of photogeneration depend on the band structure of the irradiated material and the energy of the photon. In case the irradiated material is a semiconductor material, photogeneration occurs when the energy of a photon exceeds the band gap energy, i.e., the energy difference of a band gap of the irradiated material.

The direction of travel of charged particles, i.e., the electrons and holes, in an irradiated material is sufficiently random. Thus, in the absence of any electrical bias, photogeneration of electron-hole pairs merely results in heating of the irradiated material. However, an external field can break the spatial direction of the travel of the charged particles to harness the electrons and holes formed by photogeneration.

One exemplary method of providing an electric field is to form a p-i-n junction around the irradiated material. As negative charges accumulate in the p-doped region and positive charges accumulate in the n-doped region, an electric field is generated from the direction of the n-doped region toward the p-doped region. Electrons generated in the intrinsic region drift towards the n-doped region due to the electric field, and holes generated in the intrinsic region drift towards the p-doped region. Thus, the electron-hole pairs are collected systematically to provide positive charges at the p-doped region and negative charges at the n-doped region. The p-i-n junction forms the core of this type of photovoltaic device, which provides electromotive force that can power any device connected to the positive node at the p-doped region and the negative node at the n-doped region.

Among solar cell devices, amorphous silicon based solar cells are gaining attention due to their appealing cost effectiveness. Although, the overall efficiency is still less than crystalline silicon and the degradation in performance due to prolong light exposure poses a challenge, recent development efforts promise a bright future for this technology. Amorphous Si based solar cell device performance is highly dependent on the quality of the interface between the transparent conductive oxide (TCO) and the underlying p-type silicon film. ZnO:Al, InSnO₂, and SnO:F are some known examples of TCO materials that can be employed in amorphous solar cell devices as the front contact of the cell. Such TCO materials are prone to hydrogen damage during the deposition of the p-type silicon layer. Such damage, in turn, negatively impacts the current density and hence the efficiency of the solar cell device.

### BRIEF SUMMARY

A dual transparent conductive material layer is provided between a p-doped semiconductor layer and a substrate layer of a photovoltaic device. The dual transparent conductive material layer includes a first transparent conductive material and a second transparent conductive material wherein the second transparent conductive material is nano-structured. By “nano-structured” it is meant that the second transparent conductive material has uniform, non-continuous, crystalline structures, where crystallites that are less than 50 nm in size are located therein. These structures act as a protective layer for the underlying first transparent conductive material. The nano-structured transparent conductive material of the present disclosure provides a benefit of a higher Eg of the underlying first transparent conductive material surface and a very high resilience to hydrogen plasma from the nano-structures during the formation of the p-doped semiconductor layer.

According to an aspect of the present disclosure, a photovoltaic device is provided, which includes a dual transparent conductive material layer positioned between a substrate and a p-doped semiconductor layer. The dual transparent conductive material layer includes a first transparent conductive material and a second transparent conductive material that is nano-structured. In the disclosed photovoltaic device, the first transparent conductive material has a surface that contacts a surface of the substrate, and the second transparent conductive material has a surface that contacts a surface of the p-doped semiconductor layer.

In some embodiments of the present disclosure, the first and second transparent conductive materials are transparent conductive oxide materials.

According to another aspect of the present disclosure, a method of forming a photovoltaic device is provided. The method includes providing a structure including a first transparent conductive material on a surface of a substrate. A second transparent conductive material that is nano-structured is formed on a surface of the first transparent conductive material. The first transparent conductive material and the second transparent conductive material collectively form a dual transparent conductive material layer. A p-doped semiconductor layer is the formed on a surface of the second transparent conductive material.

In one embodiment, the second transparent conductive material that is nano-structured is formed by direct deposition using, for example, chemical vapor deposition (CVD), plasma enhanced chemical vapor deposition (CVD), physical vapor deposition (PVD), and metalorgano chemical vapor deposition (MOCVD). In this embodiment, a very thin (on the order of a couple of monolayers thickness or less, i.e., sub-monolayer thickness) is deposited. A monolayer is defined herein as a film with an atomic layer thickness. Since the second transparent conductive material is very thin, the layer is not continuous and therefore nano-structures are created therein.

In another embodiment, the second transparent conductive material that is nano-structured is formed by depositing a layer of the second transparent conductive material that is thicker than the range mentioned above for the direct deposition embodiment. An etching process such as a wet chemical etching process or a dry etching process can be employed that removes excess material thickness by etching along the grain boundaries to a thickness that is capable of forming nano-structures in the second transparent conductive material.

### BRIEF DESCRIPTION OF THE DRAWINGS

FIG. 1 is a pictorial representation (through a cross sectional view) depicting an initial structure that can be employed in forming a photovoltaic device in accordance with the present disclosure, the initial structure includes a substrate and a first transparent conductive material located on a surface thereof.

FIG. 2 is a pictorial representation (through a cross sectional view) depicting the initial structure of FIG. 1 after forming a second transparent conductive material that is nano-structured on an exposed surface of the first transparent conductive material.

FIG. 3 is a pictorial representation (through a cross sectional view) depicting the structure of FIG. 2 after forming a semiconductor material stack including, from bottom to top, a p-doped semiconductor layer, an intrinsic semiconductor layer and an n-doped semiconductor layer on an exposed surface of the second transparent conductive material.

FIG. 4 is a pictorial representation (through a cross sectional view) depicting the structure of FIG. 3 after forming a first back reflector layer on an exposed surface of the n-doped semiconductor layer and after forming a second back reflector layer on an exposed upper surface of the first back reflector layer.

FIG. 5 is a pictorial representation (through a cross sectional view) after rotating by 180°, i.e., flipping, the structure shown in FIG. 4 to provide a photovoltaic device in accordance with the present disclosure.

FIG. 6 is a SEM of a nano-structured second transparent conductive material formed on a surface of a first transparent conductive material in accordance with an embodiment of the present disclosure.

### DETAILED DESCRIPTION

The present disclosure, which provides a photovoltaic device including a dual transparent conductive material layer and a method of forming such a device, will now be described in greater detail by referring to the following discussion and drawings that accompany the present application. It is observed that the drawings of the present application are provided for illustrative proposes and, as such, the drawings are not drawn to scale.

In the following description, numerous specific details are set forth, such as particular structures, components, materials, dimensions, processing steps and techniques, in order to provide an understanding of some aspects of the present disclosure. However, it will be appreciated by one of ordinary skill in the art that the various embodiments of the present disclosure may be practiced without these specific details. In other instances, well-known structures or processing steps have not been described in detail in order to avoid obscuring the disclosure.

It will be understood that when an element as a layer, region or substrate is referred to as being “on” or “over” another element, it can be directly on the other element or intervening elements may also be present. In contrast, when an element is referred to as being “directly on” or “directly over” another element, there are no intervening elements present. It will also be understood that when an element is referred to as being “beneath” or “under” another element, it can be directly beneath or under the other element, or intervening elements may be present. In contrast, when an element is referred to as being “directly beneath” or “directly under” another element, there are no intervening elements present.

As stated above, the present disclosure provides a photovoltaic device and a method of forming the same. The photovoltaic device of the present disclosure includes a dual transparent material layer positioned between a substrate and a p-doped semiconductor layer. The dual transparent material layer includes a first transparent conductive material and a second transparent conductive material that is nano-structured. In the photovoltaic device of the present disclosure, the first transparent conductive material has a surface that contacts a surface of the substrate, and the second transparent conductive material has a surface that contacts a surface of the p-doped semiconductor layer. The nano-structured second transparent conductive material acts as a protective layer for the underlying first transparent conductive material. The nano-structured transparent conductive material of the present disclosure provides a benefit of a higher Eg of the underlying first transparent conductive material surface and a very high resilience to hydrogen plasma from the nano-structures during the formation of the p-doped semiconductor layer.

The method that can be employed in forming the above mentioned photovoltaic device includes providing a first transparent conductive material on a surface of a substrate. A second transparent conductive material that is nano-structured is formed on a surface of the first transparent conductive material. The first transparent conductive material and the second transparent conductive material collectively form a dual transparent conductive material layer of this disclosure. A p-doped semiconductor layer is the formed on a surface of the second transparent conductive material.

Throughout this disclosure an element is “optical transparent” if the element is transparent in the visible electromagnetic spectral range having a wavelength from 400 nm to 800 nm.

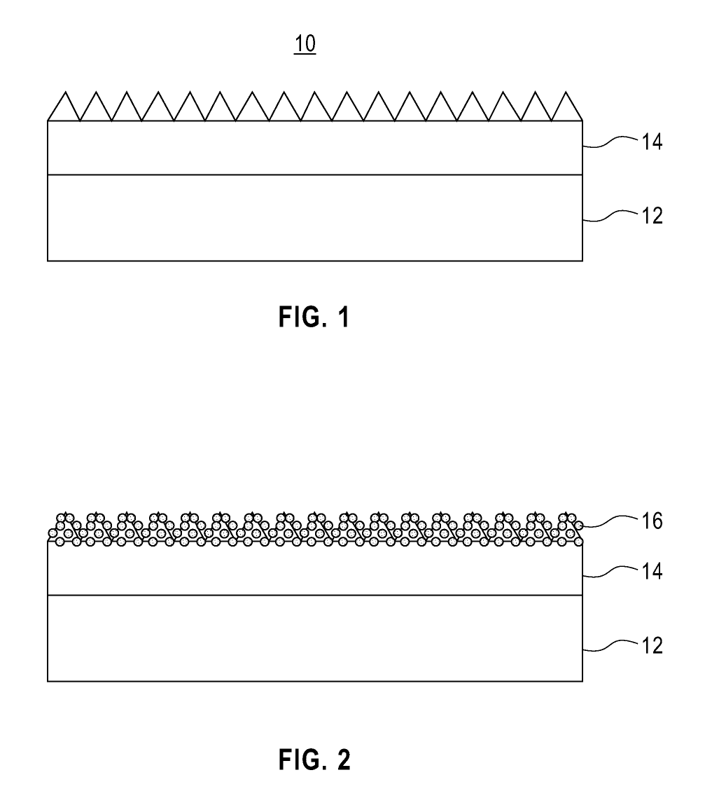

The above aspects of the present application, which are illustrated within the drawings of the present application, are now described in greater detail. Reference is first made to FIG. 1 which illustrates an initial structure 10 that can be employed in one embodiment of the present disclosure. The initial structure 10 includes a first transparent conductive material 14 located on an exposed surface of substrate 12.

The first transparent conductive material 14 typically includes an upper surface that is textured. The textured upper surface is labeled as 15 in the drawings. A textured (i.e., specially roughened) surface is used in solar cell applications to increase the efficiency of light absorption. The textured surface decreases the fraction of incident light lost to reflection relative to the fraction of incident light transmitted into the cell since photons incident on the side of an angled feature will be reflected onto the sides of adjacent angled features and thus have another chance to be absorbed. Moreover, the textured surface increases internal absorption, since light incident on an angled surface will typically be deflected to propagate through the device at an oblique angle, thereby increasing the length of the path taken to reach the device's back surface, as well as making it more likely that photons reflected from the device's back surface will impinge on the front surface at angles compatible with total internal reflection and light trapping. The texturing of the upper surface of the first transparent conductive material 14 can be performed utilizing conventional techniques well known in the art. Typically, the texturing is achieved utilizing a hydrogen based wet etch chemistry, such as, for example, etching in HCl. In some embodiments, the textured upper surface can be achieved during formation, i.e., deposition, of the first transparent conductive material 14. The RMS value of the textured surface can be in a range of a few nanometers to microns.

The initial structure 10 can be commercially purchased from known suppliers including, but not limited to, Asahi Glass Company. Alternatively, the initial structure 10 can be formed by depositing the first transparent conductive material 14 on a surface of substrate 12. The depositing of the first transparent conductive material 14 on a surface of substrate 12 can include, but is not limited to, chemical vapor deposition (CVD), plasma enhanced chemical vapor deposition (CVD), physical vapor deposition (PVD), and metalorgano chemical vapor deposition (MOCVD). As mentioned above, the upper surface of the first transparent conductive material 14 is textured. Texturing can be achieved either during deposition of the first conductive material 14 or after deposition utilizing a wet chemical etching process as mentioned above.

The substrate 12 of the initial structure 10 is a material layer that provides mechanical support to the photovoltaic device. The substrate 12 is typically transparent in the range of electromagnetic radiation at which photogeneration of electrons and holes occur within the photovoltaic device. When the photovoltaic device of the present disclosure is to be used as a solar cell, the substrate 12 can be optically transparent. In one embodiment, the substrate 12 can be a glass substrate. In another embodiment, substrate 12 can be selected from, but not limited to, plastic and/or other transparent polymer substrates. The thickness of the substrate 12 may vary. Typically, and in one embodiment of the present disclosure, substrate 12 has a thickness from 50 microns to 3 mm. In other embodiments of the present application, substrate 12 can have a thickness that is less than 50 microns and/or greater than 3 mm.

The first transparent conductive material 14 of the initial structure 10 includes a conductive material that is transparent in the range of electromagnetic radiation at which photogeneration of electrons and holes occur within the photovoltaic device structure. If the photovoltaic device is employed as a solar cell, the first transparent conductive material 14 can be optically transparent. In such an embodiment, the first transparent conductive material 14 can include a transparent conductive oxide such as, but not limited to, a fluorine-doped tin oxide (SnO₂:F), an aluminum-doped zinc oxide (ZnO:Al), tin oxide (SnO) and indium tin oxide (InSnO₂, or ITO for short). In one embodiment, the first transparent conductive material 14 is SnO₂:F.

The thickness of the first transparent conductive material 14 may vary depending on the type of transparent conductive material employed as well as the technique that was used in forming the first transparent conductive material. Typically, and in one embodiment, the thickness of the first transparent conductive material 14 is from 300 nm to 3 microns. Other thicknesses, including those less than 300 nm and/or greater than 3 microns can also be employed.

Referring now to FIG. 2, there is illustrated the initial structure 10 of FIG. 1 after forming a second transparent conductive material 16 on an exposed surface of the first transparent conductive material 14. The second transparent conductive material 16 that is formed is nano-structured. That is, the second transparent conductive material 16 has uniform, non-continuous, crystalline structures with crystallites that are less than 50 nm in size located therein.

The second transparent conductive material 16 may comprise the same or different, typically different, transparent conductive material as that of the first transparent conductive material. The second transparent conductive material can include a conductive material that is transparent in the range of electromagnetic radiation at which photogeneration of electrons and holes occur within the photovoltaic device. If the photovoltaic device is employed as a solar cell, the second transparent conductive material 16, like the first transparent conductive material 14, can be optically transparent. In such an embodiment, the second transparent conductive material 16 can include a transparent conductive oxide such as, but not limited to, a fluorine-doped tin oxide (SnO₂:F), an aluminum-doped zinc oxide (ZnO:Al), tin oxide (SnO) and indium tin oxide (InSnO₂, or ITO for short). In one embodiment, and when the first transparent conductive material 14 is SnO₂:F, the second transparent conductive material 16 can be comprised of ZnO:Al.

In embodiments in which the first and second transparent conductive materials are comprised of the same transparent conductive material, the dopant within the first and second transparent conductive materials may be different. In some embodiments, the difference in the doping between the first and second transparent conductive materials can be set such that the presence of the second transparent conductive material 16 reduces the Schottky barrier between the first transparent conductive material 14 and the p-doped semiconductor layer to be subsequently formed. In one example of such an embodiment, the first transparent conductive material 14 includes a doped transparent conductive material such as, for example, aluminum-doped zinc oxide, having a first dopant concentration, and the second transparent conductive material 16 includes the same doped transparent conductive material as the first transparent conductive material 14, yet the second transparent conductive material 16 has a second dopant concentration that is less than the first dopant concentration.

The thickness of the second transparent conductive material 16 may vary depending on the type of transparent conductive material employed as well as the technique that was used in forming the second transparent conductive material 16. Typically, and in one embodiment, the thickness of the second transparent conductive material 16 is a couple of monolayers or less, i.e., a sub-monolayer.

In one embodiment, the second transparent conductive material 16 that is nano-structured is formed by direct deposition using, for example, chemical vapor deposition (CVD), plasma enhanced chemical vapor deposition (CVD), physical vapor deposition (PVD), and metalorgano chemical vapor deposition (MOCVD). In this embodiment, a very thin (on the order of a couple of monolayers thickness or less, i.e., sub-monolayer thickness) is deposited. Since the second transparent conductive material 16 is very thin, the layer is not continuous and therefore nano-structures are created therein.

In another embodiment, the second transparent conductive material 16 that is nano-structured is formed by depositing a layer of the second transparent conductive material that is thicker than the range mentioned above for the direct deposition embodiment. An etching process such as a wet chemical etching process or a dry etching process can be employed that removes excess material thickness by etching along the grain boundaries to a thickness that is capable of forming nano-structures in the second transparent conductive material. In one example, the etch used in forming the nano-structures within the second transparent conductive material 16 includes chemical etching in HCl. The HCl used can have various dilutions and various etch times can be used. In another example, the etch used in forming the nano-structures within the second transparent conductive material 16 includes reactive ion etching (RIE) in which various chemistries including, for example, Cl based and CH₄ based chemistries, and various etching times can be employed.

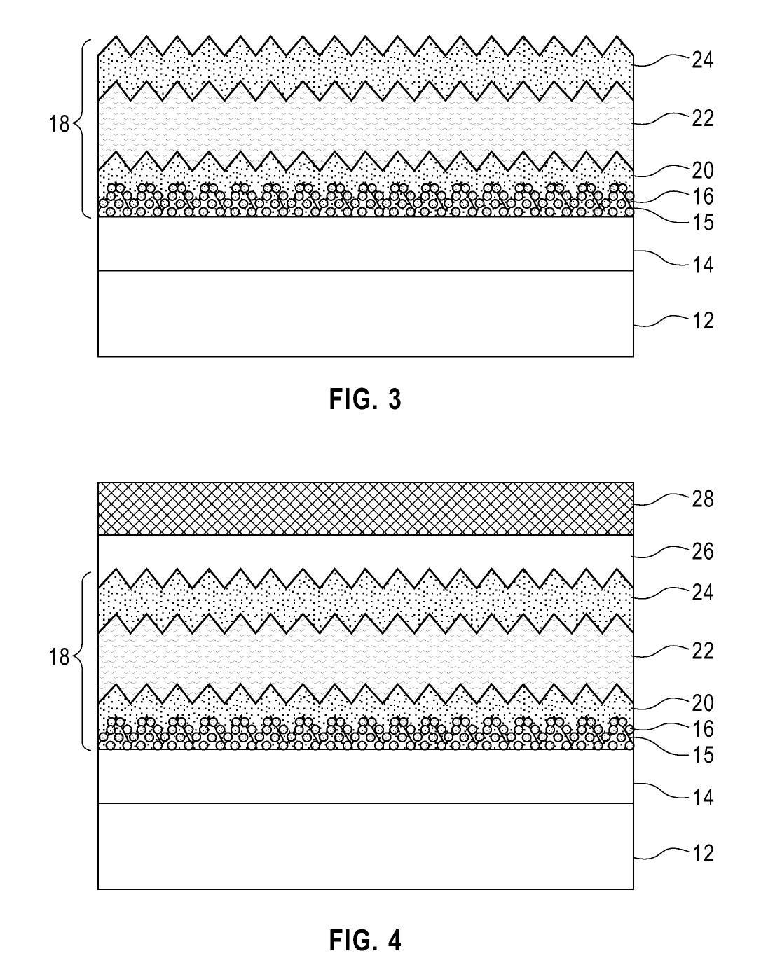

Referring to FIG. 3, there is shown the structure of FIG. 2 after forming a semiconductor material stack 18 on an exposed surface of the second transparent conductive material 16. The semiconductor material stack 18 includes, from bottom to top, a p-doped semiconductor layer 20 located on the exposed surface of the second transparent conductive material 16, an intrinsic semiconductor layer 22 located on an exposed surface of the p-doped semiconductor layer 20, and an n-doped semiconductor layer 24 located on an exposed surface of the intrinsic semiconductor layer 22.

The p-doped semiconductor layer 20 includes an amorphous or microcrystalline p-doped semiconductor-containing material. In some cases, the p-doped semiconductor layer 20 can include a hydrogenated amorphous or microcrystalline p-doped semiconductor-containing material. The presence of hydrogen in the p-doped semiconductor layer 20 can increase the concentration of free charge carriers, i.e., holes, by delocalizing the electrical charges that are pinned to defect sites. In some preferred embodiments, the p-doped semiconductor layer 20 is an amorphous p-doped semiconductor-containing material that optional includes hydrogen therein.

The term “amorphous” denotes that the p-doped semiconductor-containing material lacks a specific crystal structure. The term “p-doped semiconductor-containing material” denotes any material that has semiconductor properties such as, for example, Si, Ge, SiGe, SiC, SiGeC, GaAs, GaN, InAs, InP and all other III/V or II/VI compound semiconductors, which includes a p-type dopant therein. In one embodiment, the p-doped semiconductor layer 20 is comprised of Si. In another embodiment, the p-doped semiconductor layer 20 is comprised of Ge. In a further embodiment, the p-doped semiconductor layer 20 is comprised of SiGe, SiC or SiGeC.

The microcrystalline p-doped hydrogenated semiconductor-containing material can be a microcrystalline p-doped hydrogenated silicon-carbon alloy. In this case, a carbon-containing gas can be flown into the processing chamber during deposition of the microcrystalline p-doped hydrogenated silicon-carbon alloy. The atomic concentration of carbon in the microcrystalline p-doped hydrogenated silicon-carbon alloy of the p-doped semiconductor layer can be from 1% to 90%, and preferably from 10% to 28%. In this case, the band gap of the p-doped semiconductor layer 20 can be from 1.7 eV to 2.1 eV.

As mentioned above, the p-doped semiconductor layer 20 includes a p-type dopant therein. The concentration of p-type dopant within the p-doped semiconductor layer 20 may vary depending on the ultimate end use of the photovoltaic device and the type of dopant atom being employed. In one embodiment, the p-doped semiconductor layer 20 has a p-type dopant concentration from 1e15 atoms/cm³ to 1e17 atoms/cm³, with a p-type dopant concentration from 5e15 atoms/cm³ to 5e16 atoms/cm³ being more typical.

The p-doped semiconductor layer 20 of the semiconductor material stack 18 can be formed utilizing any epitaxial growth process that is well known to those skilled in the art. In one embodiment, the epitaxial growth process includes an in-situ doped epitaxial growth process in which the dopant atom is introduced with the semiconductor precursor source material, e.g., a silane, during the formation of the p-doped semiconductor layer. In another embodiment, an epitaxial growth process is used to form an undoped semiconductor layer, and thereafter the dopant can be introduced using one of ion implantation, gas phase doping, liquid solution spray/mist doping, and/or out-diffusion of a dopant atom from an overlying sacrificial dopant material layer that can be formed on the undoped semiconductor material, and removed after the out-diffusion process.

A hydrogenated p-doped semiconductor-containing material can be deposited in a process chamber containing a semiconductor precursor source material gas and a carrier gas. To facilitate incorporation of hydrogen in the hydrogenated p-doped semiconductor-containing material, a carrier gas including hydrogen can be employed. Hydrogen atoms in the hydrogen gas are incorporated into the deposited material to form an amorphous or microcrystalline hydrogenated p-doped semiconductor-containing material of the p-doped semiconductor layer 20.

The thickness of the p-doped semiconductor layer 20 can vary depending on the conditions of the epitaxial growth process employed. Typically, the p-doped semiconductor layer 20 has a thickness from 3 nm to 30 nm.

The intrinsic semiconductor layer 22 can include any intrinsic semiconductor-containing material that is typically, but not necessarily always hydrogenated. The intrinsic semiconductor-containing material can be amorphous or microcrystalline. Typically, the intrinsic semiconductor-containing material is amorphous. The thickness of the intrinsic semiconductor layer 22 depends on the diffusion length of electrons and holes in the intrinsic semiconductor-containing material. Typically, the thickness of the intrinsic semiconductor layer 22 is from 100 nm to 1 micron, although lesser and greater thicknesses can also be employed.

The intrinsic semiconductor layer 22 can include the same or different, typically the same, semiconductor material as that of the p-doped semiconductor layer 20. The intrinsic semiconductor layer 22 is formed utilizing any conventional epitaxial growth process including any conventional semiconductor precursor source material. In some embodiments, the p-type semiconductor material 20 and the intrinsic semiconductor layer 22 can be formed without breaking vacuum between the two deposition steps. In some embodiments, the intrinsic hydrogenated semiconductor-containing material is deposited in a process chamber containing a semiconductor precursor source gas and a carrier gas including hydrogen. Hydrogen atoms in the hydrogen gas within the carrier gas are incorporated into the deposited material to form the intrinsic hydrogenated semiconductor-containing material of the intrinsic semiconductor layer 22.

The n-doped semiconductor layer 24 of semiconductor material stack 18 includes an n-doped semiconductor-containing material, i.e., a semiconductor-containing material including an n-type dopant therein. The term “n-type dopant” is used throughout the present disclosure to denote an atom from Group VA of the Periodic Table of Elements including, for example, P, As and/or Sb. The concentration of n-type dopant within the n-doped semiconductor layer 24 may vary depending on the ultimate end use of the photovoltaic device and the type of dopant atom being employed. In one embodiment, the n-type semiconductor layer 24 typically has an n-type dopant concentration from 1e16 atoms/cm³ to 1e22 atoms/cm³, with an n-type dopant concentration from 1e19 atoms/cm³ to 1e21 atoms/cm³ being more typical. The sheet resistance of the n-type semiconductor layer 24 is typically greater than 50 ohm/sq, with a sheet resistance range of the n-type semiconductor layer 24 from 60 ohm/sq to 200 ohm/sq being more typical.

In some embodiments, the n-doped semiconductor layer 24 can be a hydrogenated material, in which case an n-doped hydrogenated semiconductor-containing material is deposited in a process chamber containing a semiconductor-material-containing reactant gas a carrier gas including hydrogen. The n-type dopants in the n-doped semiconductor layer 24 can be introduced by in-situ doping. Alternately, the n-type dopants in the n-doped semiconductor layer 24 can be introduced by subsequent introduction of dopants employing any method known in the art including those methods mentioned above in introducing a p-type dopant into p-doped semiconductor layer 20. In some embodiments, the vacuum used in forming the intrinsic semiconductor layer 22 is not broken when forming the n-doped semiconductor layer 24.

The n-doped semiconductor layer 24 can be amorphous or microcrystalline. The thickness of the n-doped semiconductor layer 24 can be from 6 nm to 26 nm, although lesser and greater thicknesses can also be employed.

The n-doped semiconductor layer 24 can include the same or different semiconductor materials as that of semiconductor layers 20 and 22. Typically, n-doped semiconductor layer 24, intrinsic semiconductor layer 22, and p-doped semiconductor layer 20 are each comprised of a same semiconductor material. In one embodiment, each of semiconductor layers 20, 22 and 24 are comprised of Si, Ge or a SiGe alloy. Typically, each of semiconductor layers 20, 22 and 24 are comprised of an amorphous semiconductor material, such as amorphous Si, that can be optionally hydrogenated.

Referring now to FIG. 4, there is illustrated the structure of FIG. 3 after forming a first back reflector layer 26 on an exposed surface of the n-doped semiconductor layer 24 and after forming a second back reflector layer 28 on an exposed upper surface of the first back reflector layer 26.

The first back reflector layer 26 can include any conductive material including a transparent conductive material that is transparent in the range of electromagnetic radiation at which photogeneration of electrons and holes occur within the photovoltaic device structure. If the photovoltaic device is employed as a solar cell, the first back reflector layer 26 can be optically transparent. For example, the first back reflector layer 26 can include one of the transparent conductive oxides mentioned above and which can also be formed utilizing one of the deposition steps mentioned in regard to forming the first transparent conductive material 14. Since such transparent conductive oxide materials are n-type materials, the contact between the first back reflector layer 26 and the n-doped semiconductor layer 24 is Ohmic, and as such, the contact resistance between the first back reflector layer 26 and the n-doped semiconductor layer 24 is negligible.

The thickness of the back reflector layer 26 may vary depending on the type of conductive material employed. The thickness of the back reflector layer 26 can be from 25 nm to 250 nm, although lesser and greater thicknesses can also be employed.

The second back reflector layer 28 includes a metallic material. Preferably, the metallic material has a high reflectivity in the range of electromagnetic radiation at which photogeneration of electrons and holes occur within the photovoltaic device structure. The metallic material can include silver, aluminum, or an alloy thereof. The metallic material used in forming the second back reflector layer 28 can include applying a metallic paste to the exposed surface of the first back reflector layer 26. The metallic paste, which includes any conductive paste such as Al paste, Ag paste or AlAg paste, is formed utilizing conventional techniques that are well known to those skilled in the art of solar cell fabrication. After applying the metallic paste, the metallic paste is heated to a sufficiently high temperature which causes the metallic paste to flow and form a metallic layer on the applied surface of the first back reflector layer 26. In one embodiment, and when an Al or Ag paste is employed, the Al or Ag paste is heated to a temperature from 700° C. to 900° C. which causes the Al or Ag paste to flow and form an Al or Ag layer. The back side metallic film 16 that is formed from the metallic paste serves as a conductive back surface field and a backside electrical contact of a solar cell.

The thickness of the second back reflector layer 28 can be from 100 nm to 1 micron, although lesser and greater thicknesses can also be employed.

In some embodiments (not shown), the first back reflector layer 26 can be omitted and the second back reflector layer 28 is formed directly on the exposed surface of the n-doped semiconductor layer 24.

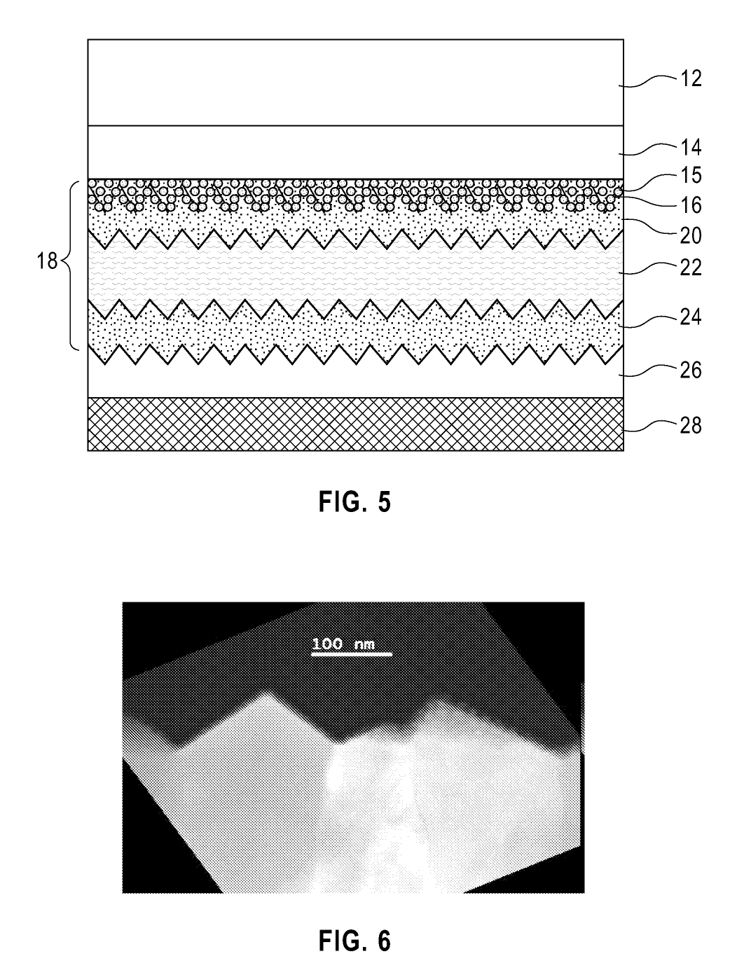

Referring now to FIG. 5, there is illustrated the structure of FIG. 4 after rotating that structure 180°. That is, the structure shown in FIG. 4 is flipped such that the substrate 10 represents the upper most layer of the device and the second back surface reflector layer 28 represents the bottom most surface of the device.

Referring now to FIG. 6 there is provided an actual SEM of a nano-structured second transparent conductive material, i.e., nano-structured ZnO:Al, formed on a surface of a surface of a first transparent conductive material, i.e., SnO:F in accordance with an embodiment of the present disclosure. The nano-structured ZnO:Al was prepared by deposition of a very thin 50 angstrom ZnO:Al film and thereafter etching the film in a solution containing 0.03% HCl for 5 seconds. The grainy structure on top of a textured surface in FIG. 6 is an example of created ZnO:Al nanostructures on SnO:F.

It is observed that the formation of the nano-structured second transparent conductive material 16 atop the first transparent conductive material 14 significantly improves the quality of the interface with the n-doped semiconductor layer 24. The improved quality of this interface, in turn, significantly improves the current density of the resultant photovoltaic device.

While the present disclosure has been particularly shown and described with respect to preferred embodiments thereof, it will be understood by those skilled in the art that the foregoing and other changes in forms and details can be made without departing from the spirit and scope of the present disclosure. It is therefore intended that the present disclosure not be limited to the exact forms and details described and illustrated, but fall within the scope of the appended claims.

What is claimed is:

1. A photovoltaic device comprising a dual transparent conductive material layer positioned between a substrate and a p-doped semiconductor layer, wherein the dual transparent conductive material layer includes a first transparent conductive material and a second transparent conductive material that is nano-structured, and wherein the first transparent conductive material has a surface that contacts a surface of the substrate, and the second transparent conductive material has a surface that contacts a surface of the p-doped semiconductor layer.

2. The photovoltaic device of claim 1 wherein said substrate is optically transparent.

3. The photovoltaic device of claim 2 wherein said substrate is a glass substrate.

4. The photovoltaic device of claim 1 wherein said first transparent conductive material is optically transparent.

5. The photovoltaic device of claim 4 wherein said first transparent conductive material is selected from a fluorine-doped tin oxide (SnO₂:F), an aluminum-doped zinc oxide (ZnO:Al), tin oxide (SnO) and indium tin oxide (InSnO₂).

6. The photovoltaic device of claim 1 wherein said second transparent conductive material is optically transparent.

7. The photovoltaic device of claim 6 wherein said second transparent conductive material is selected from a fluorine-doped tin oxide (SnO₂:F), an aluminum-doped zinc oxide (ZnO:Al), tin oxide (SnO) and indium tin oxide (InSnO₂).

8. The photovoltaic device of claim 1 wherein said first and second transparent conductive materials are comprised of a same transparent conductive oxide that is doped, wherein the dopant concentration of the first transparent conductive material differs from the dopant concentration of the second transparent conductive material.

9. The photovoltaic device of claim 8 wherein said dopant concentration of the second transparent conductive material is less than the dopant concentration of the first transparent conductive material.

10. The photovoltaic device of claim 1 wherein said p-doped semiconductor layer is an amorphous or microcrystalline p-doped semiconductor-containing material having a p-type dopant concentration from 1e15 atoms/cm³ to 1e17 atoms/cm³.

11. The photovoltaic device of claim 1 wherein said p-doped semiconductor layer includes a hydrogenated amorphous p-doped semiconductor-containing material.

12. The photovoltaic device of claim 1 further comprising an intrinsic semiconductor layer contacting said p-doped semiconductor layer, and an n-doped semiconductor layer contacting said intrinsic semiconductor layer.

13. The photovoltaic device of claim 12 wherein said intrinsic semiconductor layer includes a hydrogenated amorphous intrinsic semiconductor-containing material.

14. The photovoltaic device of claim 12 wherein said n-doped semiconductor layer includes hydrogenated n-doped amorphous semiconductor-containing material.

15. The photovoltaic device of claim 12 further comprising at least one back reflector layer located on said n-doped semiconductor layer.

16. A method of forming a photovoltaic device comprising:
providing a structure including a first transparent conductive material on a surface of a substrate;
forming a second transparent material that is nano-structured on a surface of the first transparent material; and
forming a p-doped semiconductor layer on a surface of the second transparent conductive material.

17. The method of claim 16 wherein said forming the second transparent conductive material includes a direct deposition process that is capable of forming a film that has a thickness on an order of a few monolayers or less.

18. The method of claim 17 wherein said directing depositing process includes chemical vapor deposition (CVD), plasma enhanced chemical vapor deposition (CVD), physical vapor deposition (PVD), and metalorgano chemical vapor deposition (MOCVD).

19. The method of claim 16 wherein said forming the second transparent conductive material includes depositing a layer of the second transparent conductive material that is thicker than a couple of monolayers and then performing an etching process that provides of film having a thickness of a couple of monolayers or less.

20. The method of claim 19 wherein said etching process includes wet chemical etching or dry chemical etching.

21. The method of claim 20 wherein said etching process includes wet etching with HCl.

22. The method of claim 20 wherein said etching process includes reactive ion etching with Cl based and CH₄ based chemistries.

23. The method of claim 16 further comprising forming an intrinsic semiconductor layer on an exposed surface of the p-doped semiconductor layer, and forming an n-doped semiconductor on an exposed surface of the intrinsic semiconductor layer.

24. The method of claim 23 further comprising at least one back reflector layer located on said n-doped semiconductor layer.

25. The method of claim 16 wherein said first and second transparent conductive materials are optical transparent conductive oxide materials, said transparent conductive oxide materials are the same or different from each other.
